(19) United States
(12) Patent Application Publication
(10) Pub. No.: US 2023/0096347 A1
(43) Pub. Date: Mar. 30, 2023

(54) CMOS INTEGRATION OF 2D MATERIAL BY END ETCH

(71) Applicant: Intel Corporation, Santa Clara, CA (US)

(72) Inventors: Kevin P. O'BRIEN, Portland, OR (US); Tristan A. TRONIC, Aloha, OR (US); Anandi ROY, Hillsboro, OR (US); Ashish Verma PENUMATCHA, Beaverton, OR (US); Carl H. NAYLOR, Portland, OR (US); Kirby MAXEY, Hillsboro, OR (US); Sudarat LEE, Hillsboro, OR (US); Chelsey DOROW, Portland, OR (US); Scott B. CLENDENNING, Portland, OR (US); Uygar E. AVCI, Portland, OR (US)

(21) Appl. No.: 17/485,202

(22) Filed: Sep. 24, 2021

(51) Int. Cl. H01L 27/092; H01L 29/06; H01L 29/417; H01L 29/423; H01L 29/45; H01L 29/49; H01L 29/786; H01L 21/02; H01L 21/28; H01L 21/8238; H01L 29/66

(52) U.S. Cl. CPC H01L 27/0922; H01L 29/0665; H01L 29/41733; H01L 29/42392; H01L 29/45; H01L 29/4908; H01L 29/78696; H01L 21/0259; H01L 21/28088; H01L 21/823807; H01L 21/823842; H01L 21/823871; H01L 29/66545; H01L 29/66742

(57) ABSTRACT

Embodiments disclosed herein include semiconductor devices and methods of forming such devices. In an embodiment, a semiconductor device comprises a sheet that is a semiconductor. In an embodiment a length dimension of the sheet and a width dimension of the sheet are greater than a thickness dimension of the sheet. In an embodiment, a gate structure is around the sheet, and a first spacer is adjacent to a first end of the gate structure, and a second spacer adjacent to a second end of the gate structure. In an embodiment, a source contact is around the sheet and adjacent to the first spacer, and a drain contact is around the sheet and adjacent to the second spacer.

### TECHNICAL FIELD

Embodiments of the disclosure are in the field of semiconductor structures and processing and, in particular, to nanosheet transistors.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for ever-more capacity, however, is not without issue. The necessity to optimize the performance of each device becomes increasingly significant.

Variability in conventional and currently known fabrication processes may limit the possibility to further extend them into the 10 nanometer node or sub-10 nanometer node range. Consequently, fabrication of the functional components needed for future technology nodes may require the introduction of new methodologies or the integration of new technologies in current fabrication processes or in place of current fabrication processes.

In the manufacture of integrated circuit devices, multi-gate transistors, such as tri-gate transistors and gate-all-around (GAA) transistors, have become more prevalent as device dimensions continue to scale down. Tri-gate transistors and GAA transistors are generally fabricated on either bulk silicon substrates or silicon-on-insulator substrates. In some instances, bulk silicon substrates are preferred due to their lower cost and compatibility with the existing high-yielding bulk silicon substrate infrastructure.

Scaling multi-gate transistors has not been without consequence, however. As the dimensions of these fundamental building blocks of microelectronic circuitry are reduced and as the sheer number of fundamental building blocks fabricated in a given region is increased, the constraints on the semiconductor processes used to fabricate these building blocks have become overwhelming.

### BRIEF DESCRIPTION OF THE DRAWINGS

FIG. 1 is a cross-sectional illustration of a transistor device, in accordance with an embodiment.

FIG. 2A is a perspective view illustration of a plurality of device stacks over a substrate 201, in accordance with an embodiment.

FIG. 2B is a perspective view illustration of the device stacks after an insulating layer is disposed around the device stacks and patterned to form openings adjacent to the ends of the device stacks, in accordance with an embodiment.

FIG. 2C is a cross-sectional illustration of the devices after a sacrificial material is recessed and a spacer is deposited, in accordance with an embodiment.

FIG. 2D is a cross-sectional illustration of the devices after the spacers are recessed, in accordance with an embodiment.

FIG. 2E is a cross-sectional illustration of the devices after source contacts and drain contacts are formed around the semiconductor sheets, in accordance with an embodiment.

FIG. 2F is a cross-sectional illustration of the devices after the sacrificial material is fully removed and a gate dielectric is provided around the semiconductor sheets, in accordance with an embodiment.

FIG. 3 is a cross-sectional illustration of a semiconductor device with stacked transistors, in accordance with an embodiment.

FIG. 4 illustrates a computing device in accordance with one implementation of an embodiment of the disclosure.

FIG. 5 is an interposer implementing one or more embodiments of the disclosure.

### DESCRIPTION OF THE EMBODIMENTS

Embodiments described herein comprise nanosheet transistors. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

To provide context, gate-all-around (GAA) transistor devices include channel structures such as nanowires, nanoribbons, nanosheets, and the like. The gate stack surrounds an entire perimeter of the channel structure in order to provide gate control around the entire channel. Each GAA transistor device typically includes a stack of channel structures above an underlying substrate. In embodiments disclosed herein the channel structures comprise semiconductor sheets. The sheets have a length dimension and a width dimension that is greater than a thickness dimension of the sheets. For example, the thickness dimension of the sheets may be approximately 5 nm or less, or approximately 2 nm or less. As used herein, “approximately” may refer to a value within 10% of the stated value. For example, approximately 5 nm may include a range between 4.5 nm and 5.5 nm.

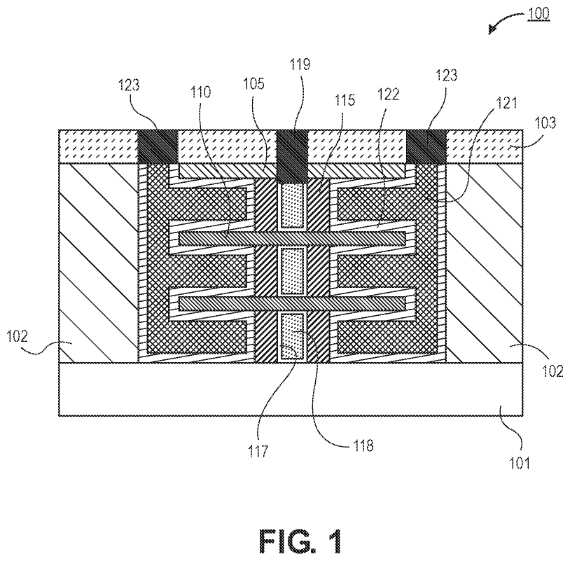

Referring now to FIG. 1, a cross-sectional illustration of a transistor device 100 is shown, in accordance with an embodiment. In an embodiment, the transistor device 100 may comprise a substrate 101. In an embodiment, the substrate 101 may be an insulating layer, such as a silicon oxide or the like. In an embodiment, the substrate 101 may be over an underlying semiconductor substrate, such as a silicon substrate or the like. The semiconductor substrate often includes a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials, such as substrates including germanium, carbon, or group III-V materials.

In an embodiment, the transistor device 100 may comprise one or more channel structures 110. The channel structure 110 may comprise a semiconductor material. In a particular embodiment, the channel structure 110 comprise silicon. In an embodiment, the channel structure 110 has a sheet-like form factor. That is, a length dimension of the channel structure 110 (left to right in FIG. 1) and a width dimension of the channel structure 110 (into and out of the plane of FIG. 1) may both be greater than a thickness dimension (up and down in FIG. 1) of the channel structure 110. For example, the thickness dimension may be approximately 5 nm or smaller, or approximately 2 nm or smaller. In the illustrated embodiment, a pair of channel structures 110 are shown. However, it is to be appreciated that one or more channel structures 110 may be used in the transistor device 100.

In an embodiment, the channel structure 110 is surrounded by a gate structure. In an embodiment, the gate structure comprises a gate dielectric 117 and a gate metal 118. The gate dielectric 117 is a conformal layer that surrounds a perimeter of the channel structure 110. For example, the gate dielectric 117 wraps into and out of the plane of FIG. 1 in order to surround the channel structure 110. The gate dielectric 117 may be, for example, any suitable oxide such as silicon dioxide or high-k gate dielectric materials. Examples of high-k gate dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric 117 to improve its quality when a high-k material is used.

In an embodiment, the gate structure further comprises a gate metal 118. While shown as a single material, it is to be appreciated that the gate metal 118 may comprise a workfunction metal and a fill metal in some embodiments. When the gate metal 118 will serve as an N-type workfunction metal, the gate metal 118 preferably has a workfunction that is between about 3.9 eV and about 4.2 eV. N-type materials that may be used to form the gate metal 118 include, but are not limited to, hafnium, zirconium, titanium, tantalum, aluminum, and metal carbides that include these elements, i.e., titanium carbide, zirconium carbide, tantalum carbide, hafnium carbide and aluminum carbide. When the gate metal 118 will serve as a P-type workfunction metal, the gate metal 118 preferable has a workfunction that is between about 4.9 eV and about 5.2 eV. P-type materials that may be used to form the gate metal 118 include, but are not limited to, ruthenium, palladium, platinum, cobalt, nickel, and conductive metal oxides, e.g., ruthenium oxide.

In an embodiment, spacers 115 may be provided on opposite ends of the gate structure 117/118. The spacers 115 may be an insulative material. For example, the spacers 115 may comprise a silicon oxide, a silicon nitride, or the like. In an embodiment, the spacers 115 may have a width (left to right in FIG. 1) that is approximately 10 nm or smaller. The spacers 115 may be in direct contact with the channel structure 110. Additionally, due to the conformal deposition of the gate dielectric 117, the gate dielectric 117 may also contact an interior surface of the spacers 115.

In an embodiment, the ends of the channel structure 110 outside of the spacers 115 may be surrounded by source contacts and drain contacts. In an embodiment, the source contacts and the drain contacts may comprise a conformal conductor 122 and a fill conductor 121. In a particular embodiment, the conformal conductor 122 comprises antimony, and the fill conductor 121 comprises gold. Though, it is to be appreciated that any suitable metal or metal alloy may be used for the conformal conductor 122 and the fill conductor 121. In other embodiments, a single conductive material may be used in the place of the conformal conductor 122 and the fill conductor 121.

In an embodiment, an insulating layer 102 may be provided around the source contacts and drain contacts. The insulating layer 102 may be an oxide, such as silicon oxide, or a nitride, such as silicon nitride. Though, it is to be appreciated that any suitable insulator may be used. In an embodiment, an insulator 103 may also be provided over a top surface of the transistor device 100. In an embodiment, the insulator 103 may be a silicon oxide or a silicon nitride, for example, in an embodiment, contacts 123 pass through the insulator 103 to contact the source contact and drain contact. A gate contact 119 may pass through the insulator 103 and a top plate 105 to reach the gate metal 118. In an embodiment, the top plate 105 may be another insulator material. The top plate 105 may have a form factor similar to that of the channel structures 110. In an embodiment, the top plate 105 is substantially parallel to the channel structures 110.

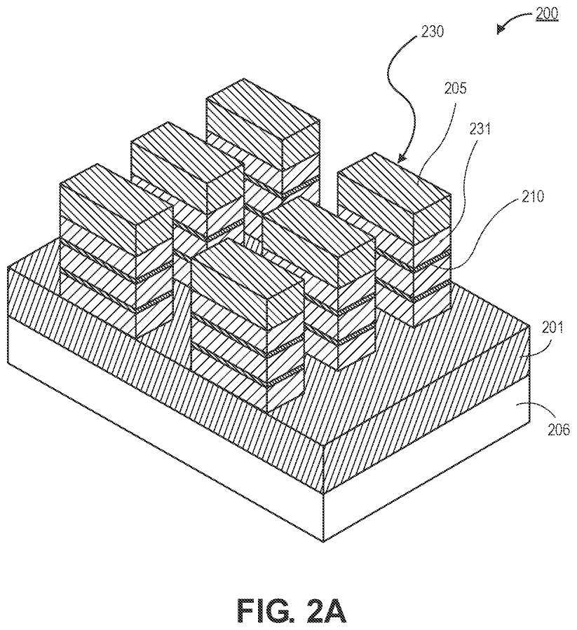

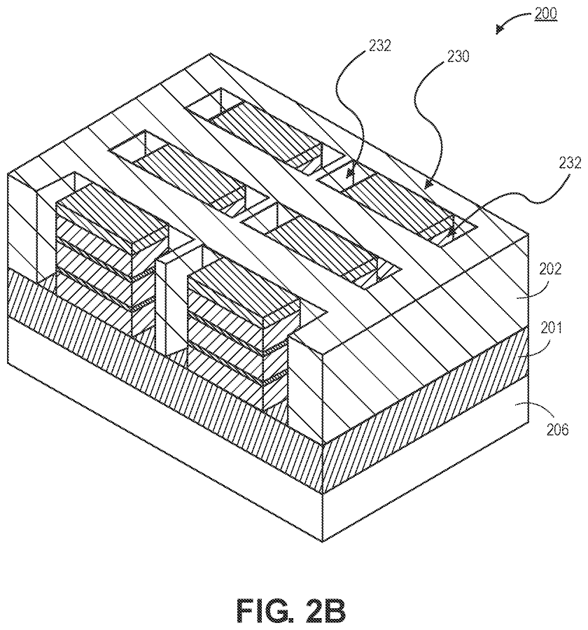

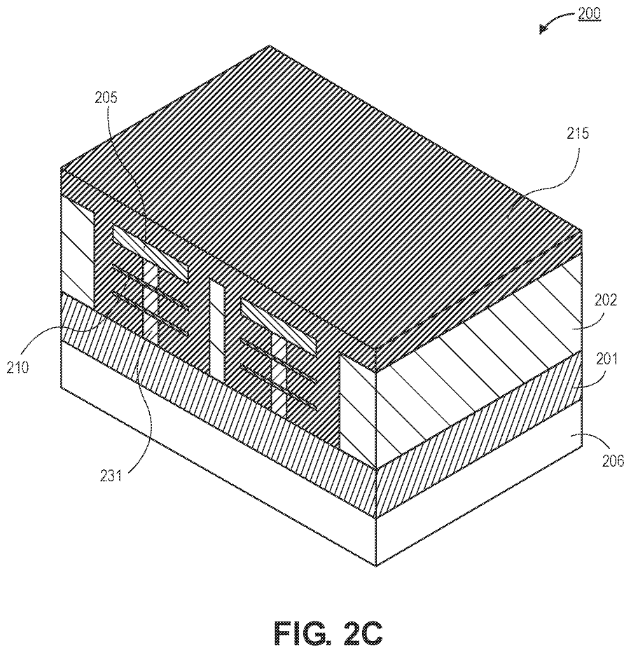

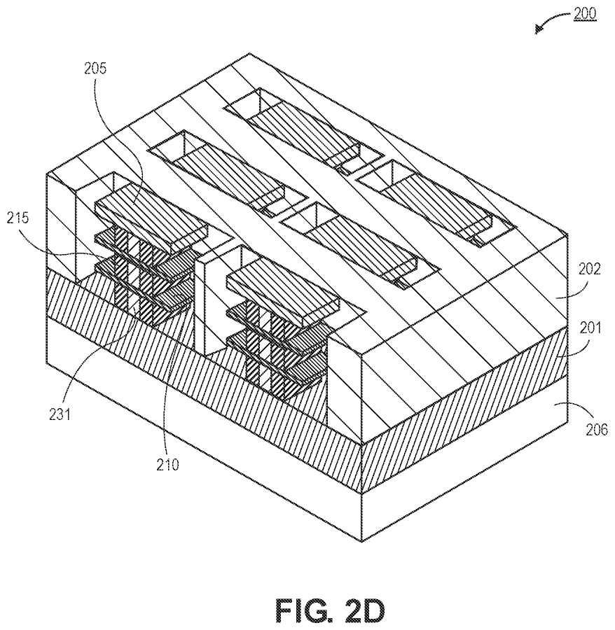

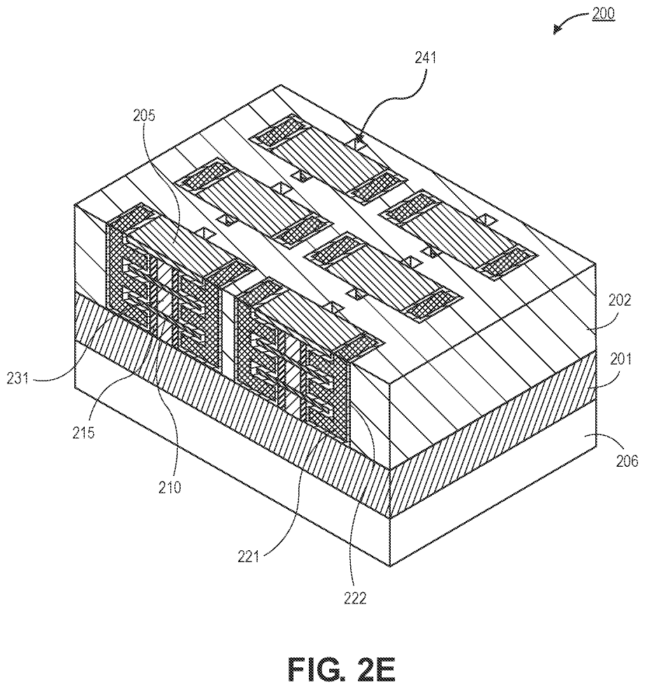

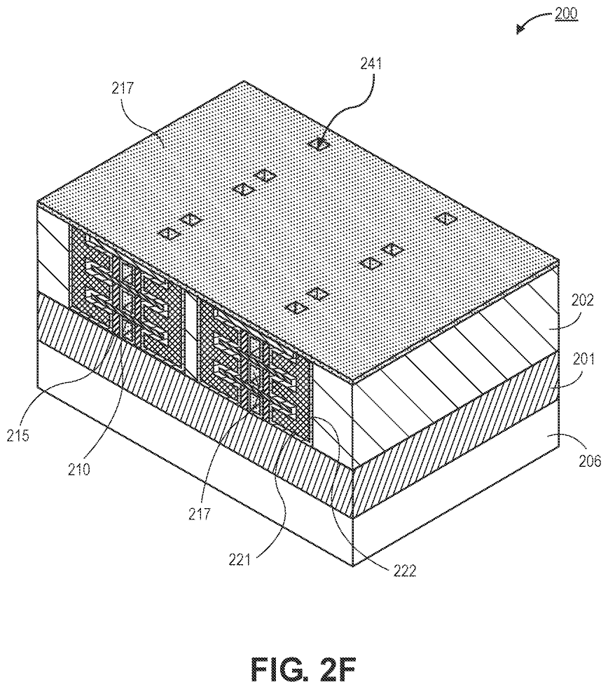

Referring now to FIGS. 2A-2F, a series of perspective view illustrations depict a process for forming a transistor device 200, in accordance with an embodiment. In an embodiment, the transistor device 200 in FIGS. 2A-2F may be substantially similar to the transistor device 100 in FIG. 1.

Referring now to FIG. 2A, a perspective view illustration of a transistor device 200 at a stage of manufacture is shown, in accordance with an embodiment. The transistor device 200 may comprise a substrate 206. The substrate 206 may be a semiconductor substrate, such as a silicon substrate. In an embodiment, a second layer 201 may be formed over the substrate 206. The second layer 201 may comprise an insulating material, such as a silicon oxide or a silicon nitride.

In an embodiment, a plurality of device stacks 230 may be provided over the second layer 201. Each device stack 230 may comprise alternating layers of a channel structure 210 and a sacrificial layer 231. For example, two channel structures 210 are shown in each device stack 230. Channel structures 210 and sacrificial layers 231 may each be a material such as, but not limited to, silicon, germanium, SiGe, GaAs, InSb, GaP, GaSb, InAlAs, InGaAs, GaSbP, GaAsSb, and InP. In a specific embodiment, channel structures 210 are silicon and sacrificial layers 231 are SiGe. An insulative plate 205 may be formed over the top of the device stacks 230. In an embodiment, the plurality of device stacks 230 may be patterned from a single larger stack of channel structures 210, sacrificial layers 231 and insulative plates 205.

In an embodiment, the device stacks 230 may be patterned in order to provide channel structures 210 with a desired form factor. For example, a width dimension and a length dimension of the channel structures 210 may be greater than a thickness dimension of the channel structures 210. In some instances the channel structures 210 may be referred to as sheets. In an embodiment, a thickness of the channel structures 210 may be approximately 5 nm or less, or approximately 2 nm or less.

Referring now to FIG. 2B, a perspective view illustration of the transistor device 200 at a state of manufacture is shown, in accordance with an embodiment. As shown, an insulating layer 202 is disposed over the device stacks 230. In an embodiment, the insulating layer 202 may be an oxide or a nitride. In an embodiment, openings 232 are formed through the insulating layer 202. The openings 232 may be positioned at the ends of each of the device stacks 230.

Referring now to FIG. 2C, a perspective view illustration of the transistor device 200 at a state of manufacture is shown, in accordance with an embodiment. As shown, the sacrificial layers 231 have been recessed, and a spacer layer 215 has been deposited. In an embodiment, the sacrificial layers 231 are recessed before the spacer layer 215 is deposited. The recessing may be implemented with a timed etch, with the etchant accessing the sacrificial layers 231 through the openings 232 at the ends of the device stacks 230. After the sacrificial layers 231 are recessed, the spacer layer 215 is deposited. In an embodiment, the spacer layer 215 fill the space vacated by the sacrificial layers 231, fill the openings 232, and deposits over a top surface of the transistor device 200. The spacer layer 215 is an insulative material. For example, the spacer layer 215 may be an oxide, a nitride, or the like. The spacer layer 215 may be a material that is etch selective to the plate 205 and the insulating layer 202.

Referring now to FIG. 2D, a perspective view illustration of the transistor device 200 at a state of manufacture is shown, in accordance with an embodiment. As shown, the spacer layer 215 has been recessed. Recessing the spacer layer 215 results in the exposure of the ends of the channel structures 210. In an embodiment, the spacer layer 215 is recessed with a timed etching process. In an embodiment, the etching process is a wet etching process.

Referring now to FIG. 2E, a perspective view illustration of the transistor device 200 at a state of manufacture is shown, in accordance with an embodiment. As shown, a source contact and a drain contact are formed on the ends of the device stacks 230. In an embodiment, the source contact and the drain contact comprise a conformal layer 222 and a fill layer 221. The conformal layer wraps around the perimeter of the channel structures 210, and the fill layer 221 fills the remaining space. In an embodiment, the conformal layer 222 and the fill layer 221 may be any suitable conductive materials. In a particular embodiment, the conformal layer 222 comprises antimony, and the fill layer 221 comprises gold. Also shown in FIG. 2E is the creation of access holes 241 through the insulating layer 202. The access holes 241 allow for access to the gate region of the transistor device 200.

Referring now to FIG. 2F, a perspective view illustration of the transistor device 200 at a state of manufacture is shown, in accordance with an embodiment. As shown, the remaining portions of the sacrificial layers 231 are removed. For example, an etchant passing through the access holes 241 may be used to etch the sacrificial layers 231. After removal of the sacrificial layers 231, a gate dielectric 217 is deposited. The gate dielectric 217 is deposited with a conformal deposition process. As such, the gate dielectric 217 deposits over the channel structure 210 and the sidewalls of the spacers 215. The dielectric 217 may also deposit over a top surface of the transistor device.

In an embodiment, after the deposition of the gate dielectric 217, a gate metal can be deposited. The gate metal fills the cavities defined by the gate dielectric 217 around the channel structures 210. The gate metal may include a workfunction metal and a fill metal. In an embodiment, the resulting structure may be similar to the structure shown in FIG. 1, and therefore will not be repeated herein.

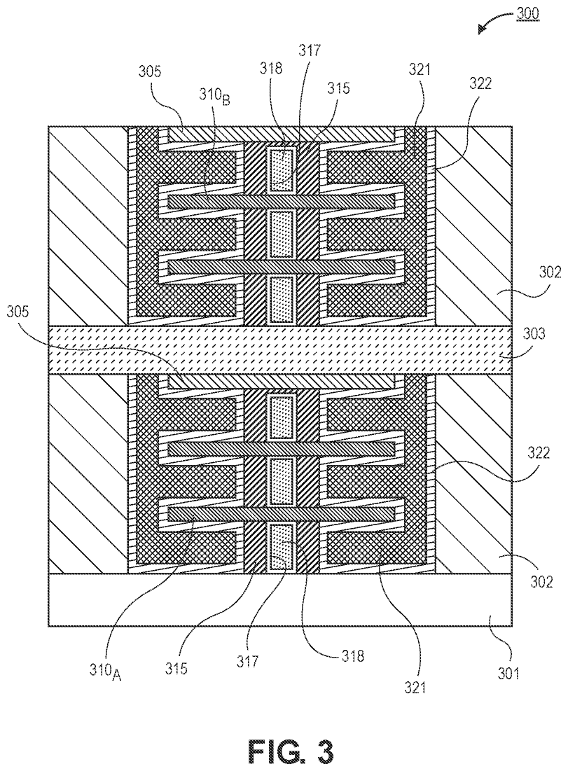

Referring now to FIG. 3, a cross-sectional illustration of a transistor device 300 is shown, in accordance with an embodiment. In an embodiment, the transistor device 300 comprises stacked transistors. A first layer of the transistors may include channel structures 310_{A} over a substrate 301. The channel structures 310_{A} may be surrounded by a gate structure that comprises a gate dielectric 317 and a gate metal 318. Spacers 315 may be formed adjacent to the gate structure. In an embodiment, a source contact and a drain contacts may wrap around ends of the channel structures 310_{A}. The source contact and the drain contact may comprise a conformal material 322 and a fill material 321. In an embodiment, a top plate 305 may be provided over the transistor, and insulating layers 302 may surround the source contact and the drain contact.

In an embodiment, an insulating layer 303 may separate the bottom transistor from the top transistor. In some embodiments, conductive interconnects (not shown) may pass through the insulating layer 303 in order to couple together the top transistor and the bottom transistor. In an embodiment, the top transistor may be substantially similar to the bottom transistor. For example, channel structures 310E may be surrounded by a gate structure (i.e., gate dielectric 317 and gate metal 318). Spacers 315 are adjacent to the gate structure, and contacts 321 and 322 surround ends of the channel structures 310B. An insulating layer 302 surrounds the top transistor, and a top plate 305 covers a top surface of the top transistor.

While two stacked transistors are shown, it is to be appreciated that any number of stacked transistors may be included in accordance with embodiments described herein. Additionally, it is to be appreciated that there is flexibility in the conductivity types of the top and bottom transistors. For example, the bottom transistor may be a P-type transistor and the top transistor may be an N-type transistor. The opposite conductivities may also be used, where the bottom transistor may be an N-type transistor and the top transistor may be a P-type transistor. Of course, the top and bottom transistors may be the same conductivity type in some embodiments as well.

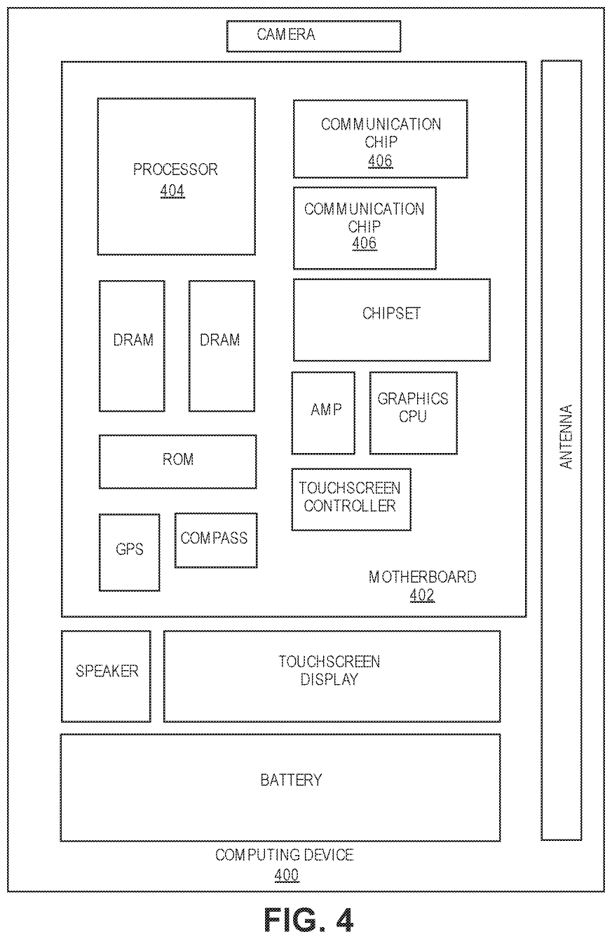

FIG. 4 illustrates a computing device 400 in accordance with one implementation of an embodiment of the disclosure. The computing device 400 houses a board 402. The board 402 may include a number of components, including but not limited to a processor 404 and at least one communication chip 406. The processor 404 is physically and electrically coupled to the board 402. In some implementations the at least one communication chip 406 is also physically and electrically coupled to the board 402. In further implementations, the communication chip 406 is part of the processor 404.

Depending on its applications, computing device 400 may include other components that may or may not be physically and electrically coupled to the board 402. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 406 enables wireless communications for the transfer of data to and from the computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 406 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 400 may include a plurality of communication chips 406. For instance, a first communication chip 406 may be dedicated to shorter range wireless communications such as Wi-Fi and Bluetooth and a second communication chip 406 may be dedicated to longer range wireless communications such as GPS, EDGE, GPRS, CDMA, WiMAX, LTE, Ev-DO, and others.

The processor 404 of the computing device 400 includes an integrated circuit die packaged within the processor 404. In an embodiment, the integrated circuit die of the processor may comprise a non-planar transistor device with semiconductor sheets that are surrounded by a gate structure and source/drain contacts, as described herein. The term “processor” may refer to any device or portion of a device that processes electronic data from registers and/or memory to transform that electronic data into other electronic data that may be stored in registers and/or memory.

The communication chip 406 also includes an integrated circuit die packaged within the communication chip 406. In an embodiment, the integrated circuit die of the communication chip may comprise a non-planar transistor device with semiconductor sheets that are surrounded by a gate structure and source/drain contacts, as described herein.

In further implementations, another component housed within the computing device 400 may comprise a non-planar transistor device with semiconductor sheets that are surrounded by a gate structure and source/drain contacts, as described herein.

In various implementations, the computing device 400 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 400 may be any other electronic device that processes data.

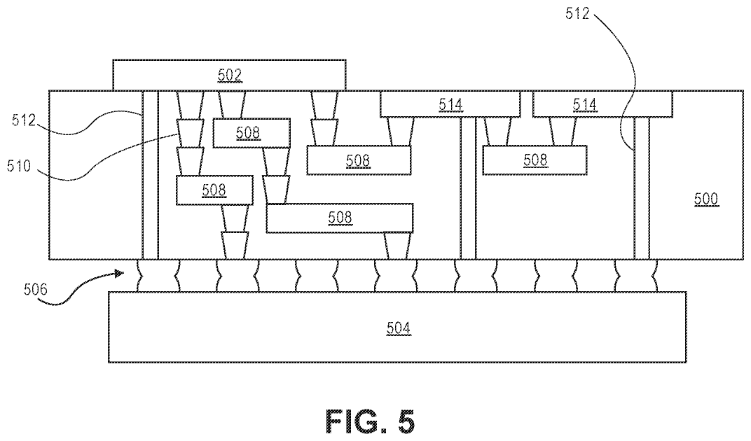

FIG. 5 illustrates an interposer 500 that includes one or more embodiments of the disclosure. The interposer 500 is an intervening substrate used to bridge a first substrate 502 to a second substrate 504. The first substrate 502 may be, for instance, an integrated circuit die. The second substrate 504 may be, for instance, a memory module, a computer motherboard, or another integrated circuit die. In an embodiment, one of both of the first substrate 502 and the second substrate 504 may comprise a non-planar transistor device with semiconductor sheets that are surrounded by a gate structure and source/drain contacts, in accordance with embodiments described herein. Generally, the purpose of an interposer 500 is to spread a connection to a wider pitch or to reroute a connection to a different connection. For example, an interposer 500 may couple an integrated circuit die to a ball grid array (BGA) 506 that can subsequently be coupled to the second substrate 504. In some embodiments, the first and second substrates 502/504 are attached to opposing sides of the interposer 500. In other embodiments, the first and second substrates 502/504 are attached to the same side of the interposer 500. And in further embodiments, three or more substrates are interconnected by way of the interposer 500.

The interposer 500 may be formed of an epoxy resin, a fiberglass-reinforced epoxy resin, a ceramic material, or a polymer material such as polyimide. In further implementations, the interposer 500 may be formed of alternate rigid or flexible materials that may include the same materials described above for use in a semiconductor substrate, such as silicon, germanium, and other group III-V and group IV materials.

The interposer 500 may include metal interconnects 508 and vias 510, including but not limited to through-silicon vias (TSVs) 512. The interposer 500 may further include embedded devices 514, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 500. In accordance with embodiments of the disclosure, apparatuses or processes disclosed herein may be used in the fabrication of interposer 500.

Thus, embodiments of the present disclosure may comprise a transistor device with semiconductor sheets that are surrounded by a gate structure and source/drain contacts.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: a semiconductor device, comprising: a sheet comprising a semiconductor, wherein a length dimension of the sheet and a width dimension of the sheet are greater than a thickness dimension of the sheet; a gate structure around the sheet; a first spacer adjacent to a first end of the gate structure; a second spacer adjacent to a second end of the gate structure; a source contact around the sheet and adjacent to the first spacer; and a drain contact around the sheet and adjacent to the second spacer.

Example 2: the semiconductor device of Example 1, wherein the gate structure comprises a gate dielectric and a conductor.

Example 3: the semiconductor device of Example 2, wherein the conductor comprises a first metal layer that is conformal, and a second metal layer that is a fill material.

Example 4: the semiconductor device of Examples 1-3, wherein the source contact and the drain contact comprise: a first metal layer that is conformal around the sheet; and a second metal layer that is a fill material.

Example 5: the semiconductor device of Example 4, wherein the first metal layer comprises antimony, and wherein the second metal layer comprises gold.

Example 6: the semiconductor device of Examples 1-7, further comprising: a second sheet over the sheet.

Example 7: the semiconductor device of Example 6, wherein the gate structure is around the second sheet, wherein the source contact is around the second sheet, and wherein the drain contact is around the second sheet.

Example 8: the semiconductor device of Examples 1-7, further comprising: a plate above the sheet, wherein the plate is substantially parallel to the sheet, and wherein the plate comprises an insulator material.

Example 9: the semiconductor device of Examples 1-8, wherein the thickness dimension of the sheet is 5 nm or smaller.

Example 10: the semiconductor device of Examples 1-9, further comprising: a second semiconductor device over the semiconductor device, wherein the second semiconductor device comprises: a second sheet comprising a semiconductor, wherein a length dimension of the second sheet and a width dimension of the second sheet are greater than a thickness dimension of the second sheet; a second gate structure around the second sheet; a third spacer adjacent to a first end of the second gate structure; a fourth spacer adjacent to a second end of the second gate structure; a second source contact around the second sheet and adjacent to the third spacer; and a second drain contact around the second sheet and adjacent to the fourth spacer.

Example 11: the semiconductor device of Example 10, wherein the sheet comprises an N-type semiconductor, and wherein the second sheet comprises a P-type semiconductor.

Example 12: the semiconductor device of Example 10, wherein the sheet comprises a P-type semiconductor, and wherein the second sheet comprises an N-type semiconductor.

Example 13: the semiconductor device of Examples 10-12, wherein the second semiconductor device is spaced apart from the semiconductor device by a layer, wherein the layer is an insulator material.

Example 14: a method of forming a semiconductor device, comprising: forming a stack comprising alternating sheet layers and sacrificial layers, wherein the sheet layers comprise a semiconductor material; patterning the stack to form a device stack; disposing an insulator layer around the device stack; forming openings through the insulator layer at ends of the device stack; recessing the sacrificial layers; depositing a spacer adjacent to the recessed sacrificial layers; forming a source contact on a first end of the sheet layers; forming a drain contact on a second end of the sheet layers; removing the sacrificial layers; and forming a gate structure within the spacer.

Example 15: the method of Example 14, wherein the sheet layers comprises two sheet layers.

Example 16: the method of Example 14 or Example 15, wherein the gate structure comprises: a gate dielectric; a workfunction metal; and a fill metal.

Example 17: the method of Examples 14-16, wherein the source contact and the drain contact comprise: a conformal contact layer; and a fill contact layer.

Example 18: the method of Examples 14-17, wherein a thickness of the sheet layers is 5 nm or smaller.

Example 19: an electronic system, comprising: a board; a package substrate coupled to the board; and a die coupled to the package substrate, wherein the die comprises a semiconductor device comprising: a sheet comprising a semiconductor, wherein a length dimension of the sheet and a width dimension of the sheet are greater than a thickness dimension of the sheet; a gate structure around the sheet; a first spacer adjacent to a first end of the gate structure; a second spacer adjacent to a second end of the gate structure; a source contact around the sheet and adjacent to the first spacer; and a drain contact around the sheet and adjacent to the second spacer.

Example 20: the electronic system of Example 19, wherein the thickness dimension of the sheet is 5 nm or smaller.

What is claimed is:

1. A semiconductor device, comprising:
a sheet comprising a semiconductor, wherein a length dimension of the sheet and a width dimension of the sheet are greater than a thickness dimension of the sheet;
a gate structure around the sheet;
a first spacer adjacent to a first end of the gate structure;
a second spacer adjacent to a second end of the gate structure;
a source contact around the sheet and adjacent to the first spacer; and
a drain contact around the sheet and adjacent to the second spacer.

2. The semiconductor device of claim 1, wherein the gate structure comprises a gate dielectric and a conductor.

3. The semiconductor device of claim 2, wherein the conductor comprises a first metal layer that is conformal, and a second metal layer that is a fill material.

4. The semiconductor device of claim 1, wherein the source contact and the drain contact comprise:
a first metal layer that is conformal around the sheet; and
a second metal layer that is a fill material.

5. The semiconductor device of claim 4, wherein the first metal layer comprises antimony, and wherein the second metal layer comprises gold.

6. The semiconductor device of claim 1, further comprising:
a second sheet over the sheet.

7. The semiconductor device of claim 6, wherein the gate structure is around the second sheet, wherein the source contact is around the second sheet, and wherein the drain contact is around the second sheet.

8. The semiconductor device of claim 1, further comprising:
a plate above the sheet, wherein the plate is substantially parallel to the sheet, and wherein the plate comprises an insulator material.

9. The semiconductor device of claim 1, wherein the thickness dimension of the sheet is 5 nm or smaller.

10. The semiconductor device of claim 1, further comprising:
a second semiconductor device over the semiconductor device, wherein the second semiconductor device comprises:
a second sheet comprising a semiconductor, wherein a length dimension of the second sheet and a width dimension of the second sheet are greater than a thickness dimension of the second sheet;
a second gate structure around the second sheet;
a third spacer adjacent to a first end of the second gate structure;
a fourth spacer adjacent to a second end of the second gate structure;
a second source contact around the second sheet and adjacent to the third spacer; and
a second drain contact around the second sheet and adjacent to the fourth spacer.

11. The semiconductor device of claim 10, wherein the sheet comprises an N-type semiconductor, and wherein the second sheet comprises a P-type semiconductor.

12. The semiconductor device of claim 10, wherein the sheet comprises a P-type semiconductor, and wherein the second sheet comprises an N-type semiconductor.

13. The semiconductor device of claim 10, wherein the second semiconductor device is spaced apart from the semiconductor device by a layer, wherein the layer is an insulator material.

14. A method of forming a semiconductor device, comprising:
forming a stack comprising alternating sheet layers and sacrificial layers, wherein the sheet layers comprise a semiconductor material;
patterning the stack to form a device stack;
disposing an insulator layer around the device stack;
forming openings through the insulator layer at ends of the device stack;
recessing the sacrificial layers;
depositing a spacer adjacent to the recessed sacrificial layers;
forming a source contact on a first end of the sheet layers;
forming a drain contact on a second end of the sheet layers;
removing the sacrificial layers; and
forming a gate structure within the spacer.

15. The method of claim 14, wherein the sheet layers comprises two sheet layers.

16. The method of claim 14, wherein the gate structure comprises:
a gate dielectric;
a workfunction metal; and
a fill metal.

17. The method of claim 14, wherein the source contact and the drain contact comprise:
a conformal contact layer; and
a fill contact layer.

18. The method of claim 14, wherein a thickness of the sheet layers is 5 nm or smaller.

19. An electronic system, comprising:
a board;
a package substrate coupled to the board; and
a die coupled to the package substrate, wherein the die comprises a semiconductor device comprising:
a sheet comprising a semiconductor, wherein a length dimension of the sheet and a width dimension of the sheet are greater than a thickness dimension of the sheet;
a gate structure around the sheet;
a first spacer adjacent to a first end of the gate structure;
a second spacer adjacent to a second end of the gate structure;
a source contact around the sheet and adjacent to the first spacer; and
a drain contact around the sheet and adjacent to the second spacer.

20. The electronic system of claim 19, wherein the thickness dimension of the sheet is 5 nm or smaller.
